(19) United States
(12) Patent Application Publication
(10) Pub. No.: US 2011/0168260 A1
(43) Pub. Date: Jul. 14, 2011

(54) REFLECTIVE POLYHEDRON OPTICAL COLLECTOR AND METHOD OF USING THE SAME

(75) Inventor: Philip L. Gleckman, South Pasadena, CA (US)

(73) Assignee: Energy Innovations Inc., Pasadena, CA (US)

(21) Appl. No.: 12/197,109

(22) Filed: Aug. 22, 2008

Related U.S. Application Data
(60) Provisional application No. 60/966,027, filed on Aug. 24, 2007.

(51) Int. Cl. H01L 31/0232; G02B 5/09; B23P 11/00

(52) U.S. Cl. 136/259; 359/853; 29/428

(57) ABSTRACT

Various embodiments relate to reflectors comprising a tapered polyhedron including a plurality of substantially planar facets. The reflector may comprise an input end or aperture that is larger than an output end or aperture. The input aperture or end may have a different shape and/or orientation than an output end or aperture. Some embodiments relate to “developable” geometries made of substantially planar facets which, when folded, form a tapered hollow polyhedron that can efficiently receive light (e.g., from a primary reflector or lens) and direct light onto a photovoltaic cell.

### CROSS-REFERENCE TO RELATED APPLICATIONS

This application claims the benefit of U.S. provisional application Ser. No. 60/966,027, entitled “REFLECTIVE SECONDARY OPTICAL ELEMENT WITH 4-FOLD SYMMETRY”, filed on Aug. 24, 2007, which is incorporated by reference in its entirety.

### BACKGROUND OF THE INVENTION

1. Field of the Invention

Various embodiments relate to reflectors comprising a tapered polyhedron comprising an input end or aperture and an output end or aperture. The input end or aperture may have different shape and/or orientation than the output end or aperture.

2. Description of the Related Art

Solar concentrators are designed to collect solar energy by collecting incident light and concentrating it onto a receiver where it is generally converted to electricity or heat. The light is typically concentrated onto the receiver with a primary focusing element, such as a lens or mirror. A secondary optical element near the focal plane of the primary may be used to improve the receiver response relative to the primary. The secondary may, for example: (1) transform the irradiance produced by the primary to one more favorable to the receiver, or (2) expand the angular range over which the concentrator can vary and still collect incident light, which is referred to herein as the tracking error range, or (3) collect the spread light due to aberrations in the primary. The improvement in the light collection or tracking error tolerance is generally the result of the fact that the input aperture on the secondary is larger than the output aperture, thereby increasing the effective target size for the solar image beyond physical width of the cell.

The most common types of secondary optical elements fall into two categories: glass prisms employing total internal reflection and mirrors. Both types can transform the highly-peaked substantially disk-shaped irradiance from a primary reflector or lens to a quasi-uniform square light distribution, which makes them suitable for use with substantially square photovoltaic cells. The performance of glass prisms can be sensitive to the presence of dust or dirt on the input face as well as the quality of the bond between the prism and cell. A reflective secondary such as especially one made from sheet metal, in contrast, may be less expensive to fabricate, easier to mount to the receiver, and relatively less vulnerable to environmental contamination.

The geometry of a conventional reflective secondary is shown in plan view in FIG. 1 looking down the longitudinal axis onto the input aperture. For typical applications where the primary is around f/1, however, the optical throughput of the secondary is inadequate and subject to further improvement.

### SUMMARY

Various embodiments of the invention include a reflective element that directs light onto a photovoltaic cell, for example. This element may comprise a secondary reflector that works in cooperation with a larger primary lens or reflector. This element may comprise several (e.g., 4, 3, 2, or less) sheets such as pieces of sheet metal folded to form a hollow tubular structure through which light can pass. The location of the folds may be such that the tubular structure is “developable” (i.e., having a zero Gaussian curvature) and thus easy to manufacture, while still providing good light uniformity on the PV cell.

Various embodiments of the invention comprise a reflector comprising a tapered polyhedron, a rectangular output end at an end of the tapered polyhedron, and a polygon input end at an end of the tapered polyhedron opposite the rectangular output end. The tapered polyhedron comprises a plurality of substantially planar facets wherein the inner surface of the tapered polyhedron is reflective. The tapered polyhedron has an optical axis extending therethrough. Some of the substantially planar facets have surface normals that intersect the optical axis and some of the substantially planar facets have surface normals skew to the optical axis. Additionally, the polygon comprises five or more sides.

Certain embodiments of the invention comprise an optical system comprising a reflector comprising and a solar cell wherein the reflector is disposed to direct light along an optical path to the solar cell. The reflector comprises a tapered polyhedron, a rectangular output end at an end of the tapered polyhedron, and a polygon input end at an end of the tapered polyhedron opposite the rectangular output end. The tapered polyhedron comprises a plurality of substantially planar facets wherein the inner surface of the tapered polyhedron is reflective. The tapered polyhedron has an optical axis extending therethrough. Some of the substantially planar facets have surface normals that intersect the optical axis and some of the substantially planar facets have surface normals that do not intersect the optical axis. Additionally, the polygon comprises five or more sides.

Some embodiments of the invention comprise a method of manufacturing a solar energy conversion assembly. The method comprises providing a reflector and disposing the reflector such that light output from the output end of the reflector is directed towards a solar cell. The reflector comprises a tapered polyhedron, a rectangular output end at an end of the tapered polyhedron, and a polygon input end at an end of the tapered polyhedron opposite the rectangular output end. The tapered polyhedron comprises a plurality of substantially planar facets, wherein the inner surface of the tapered polyhedron is reflective. The tapered polyhedron has an optical axis extending therethrough. Some of the substantially planar facets have surface normals that intersect the optical axis and some of the substantially planar facets have surface normals skew to the optical axis. Additionally, the polygon comprises five or more sides.

Various embodiments of the invention comprise a reflector comprising a tapered polyhedron, a polygon input end at an end of the tapered polyhedron, and a polygon output end at an end of the tapered polyhedron opposite the input end. The tapered polyhedron comprises a plurality of substantially planar facets, wherein the inner surface of the tapered polyhedron is reflective. The tapered polyhedron has an optical axis extending therethrough. Some of the substantially planar facets have surface normals that intersect the optical axis and some of the substantially planar facets have surface normals skew to the optical axis. Additionally, a number of sides associated with the polygon of the input end is different than a number of sides associated with the polygon of the output end.

Certain embodiments of the invention comprise an optical system comprising a reflector and a solar cell. The reflector is configured to direct light towards the solar cell. The reflector comprises a tapered polyhedron a polygon input end at an end of the tapered polyhedron and a polygon output end at an end of the tapered polyhedron opposite the input end. The tapered polyhedron comprises a plurality of substantially planar facets, wherein the inner surface of the tapered polyhedron is reflective. The tapered polyhedron has an optical axis extending therethrough. Some of the substantially planar facets have surface normals that intersect the optical axis and some of the substantially planar facets have surface normals that do not intersect the optical axis. Additionally, a number of sides associated with the polygon of the input end is different than a number of sides associated with the polygon of the output end.

Some embodiments of the invention comprise a method of manufacturing an assembly for solar energy conversion. The method comprises providing a reflector and disposing the reflector to direct light along an optical path to the solar cell. The reflector comprises a tapered polyhedron, a polygon input end at an end of the tapered polyhedron, and a polygon output end at an end of the tapered polyhedron opposite the input end. The tapered polyhedron comprises a plurality of substantially planar facets, wherein the inner surface of the tapered polyhedron is reflective. The tapered polyhedron has an optical axis extending therethrough. Some of the substantially planar facets have surface normals that intersect the optical axis and some of the substantially planar facets have surface normals skew to the optical axis. Additionally, a number of sides associated with the polygon of the input end is different than a number of sides associated with the polygon of the output end.

### BRIEF DESCRIPTION OF THE DRAWINGS

FIG. 1 shows the geometry of a conventional reflective secondary along its longitudinal axis.

FIG. 2 shows a reflector with a rectangular output end and an octogonal input end, being shown along its longitudinal axis.

FIGS. 3A and 3B show the reflector of FIG. 2 with an upper-side and lower-side perspective view.

FIG. 4 shows a reflector with a rectangular output end and an octagonal input end, being shown along its longitudinal axis.

FIGS. 5A and 5B show a reflector with a rectangular output end and a circular input end, being shown along its longitudinal axis.

FIG. 6 shows a reflector with a rectangular output end and a rectangular input end, being shown along its longitudinal axis, wherein the rectangle of the input end is rotated with respect to the rectangle of the output end.

FIGS. 7 and 8 show side views of the secondary reflector with octagonal input aperture shown in FIGS. 2, 3A, and 3B.

FIGS. 9A and 9B show a section of the tapered polyhedron from the reflector of FIGS. 7 and 8.

FIGS. 10A and 10B show a section of the tapered polyhedron from the reflector of FIGS. 7 and 8 with a mounting tab.

FIG. 11A shows a support for mounting a complete secondary assembly.

FIG. 11B shows the secondary reflector integrated with the support.

FIG. 12 shows a primary lens disposed above the secondary reflector.

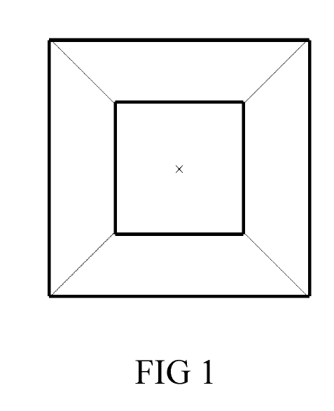

### DETAILED DESCRIPTION OF THE PREFERRED EMBODIMENT

Some embodiments relate to the design of a high-efficiency reflective secondary that provides improved optical uniformity across an output aperture, improved tracking error tolerance, improved collection of light spread, and/or reduced manufacturing cost. Some embodiments relate to “developable” geometries made of substantially planar facets which, when folded, form a tapered hollow polyhedron that can efficiently receive light (e.g., from a primary reflector or lens) and direct light onto a photovoltaic cell. In various embodiments, the tapered hollow polyhedron can be thus fabricated from 2 sheets folded and assembled together. (In other embodiments 3 or 4 sheets or even 1 sheet may be used to form the complete tapered hollow reflective polyhedron). In some instances, a reflector disclosed herein receives light characterized by a particular beam shape and efficiently outputs the light in a different beam shape, such as a shape corresponding to a photovoltaic cell. Depending on the input aperture and embodiment, the facets of the secondary may have normal vectors that intersect the longitudinal axis and exhibit quadrature symmetry.

In some embodiments, an optical element reflector (e.g., a secondary) is provided that comprises an input end with a different shape and/or orientation than an output end. A plurality of facets (e.g., planar facets) may connect the two ends. In some instances, a first group of facets of the reflector extend from vertices of the input end to a side (e.g., for polygonal shapes) or section (e.g., for rounds shapes) of the output end, and a second group of facets of the reflector extend from a vertices of the output end to a side or section of the input end. In various embodiments, the output end is smaller in aperture size (e.g., in area) than the input end and the optical element reflector is tapered to provide such reduction in size.

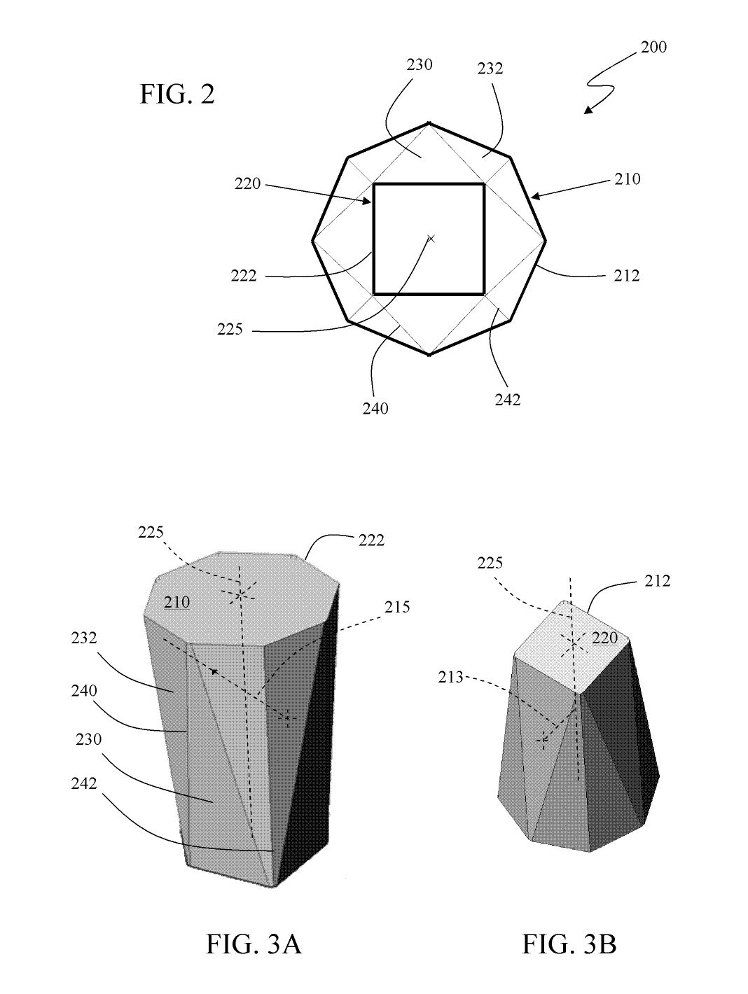

FIG. 2 illustrates a top-down view of one embodiment of reflector 200 such as a secondary reflector for use in a solar concentrator. In addition, FIG. 3A shows an upper-side perspective view the secondary 200, while FIG. 3B shows a lower-side perspective view of the secondary. The secondary 200 comprises a tapered polyhedron with an input aperture 210 and output aperture 220. The input aperture 210 (opaque in FIG. 3A) refers to an opening through which light is received from a primary concentrating reflector or lens. The output aperture 220 (opaque in FIG. 3B) refers to an opening through which light reflected in the secondary, or passed through the secondary, is directed onto a photovoltaic cell or other receiver to which it is optically coupled. In the example reflector 200 shown in FIGS. 2, 3A, and 3B, the input aperture 210 has six sides 212 and the output aperture 222 has four sides. Although shown with opaque shading in FIGS. 3A and 3B, in various embodiments, the secondary reflector 200 is hollow with an open region therethrough. Accordingly, the input and output apertures 210, 220 may be open. In other embodiments, the input and/or output aperture 210, 220 may include an optically transmissive element such as a transparent plate. In some embodiments, such as those shown in FIGS. 2, 3A and 3B, the output aperture 220 is characterized by a polygon having a lesser number of sides than that of the input aperture 210. In other embodiments, the output aperture 220 is characterized by a polygon with a greater number of the same number of sides as the input aperture 210.

In various embodiments, the tapered polyhedron that joins the input aperture 210 and output aperture 220 is “developable,” i.e., having a zero Gaussian curvature. A developable surface indicates that the surface may be made by cutting and folding (or bending) sheet metal, for example, into a 3 dimensional structure that has increased depth compared to the sheets of metal unfolded. The secondary has no curves or complex curvature which might require the use of stamping, pressing, or molding to form. The folds include first fold 240 and second fold 242, which are configured to connect vertices on the input aperture to vertices on the output aperture. The folds give rise to a plurality of facets (e.g., planar facets) including a first facet 230 and second facet 232. In the example shown in FIGS. 3A and 3B, the facets are triangular. For example, the first group of facets 230 are substantially isosceles triangles and the second group of facets 232 are right triangles. Some (e.g., 4) of the triangular facets have bases corresponding to sides of the square input aperture and vertices corresponding to corners (e.g., 8) of the octagonal output aperture. Other ones of the triangular facets (e.g., 8) have bases corresponding to sides of the octagonal input aperture and vertices corresponding to corners (e.g., 4) of the square output aperture. Between the triangles are the folds. In the example shown in FIGS. 3A and 3B, the reflector 200 has twelve planar triangular facets and twelve folds therebetween. Accordingly, in various embodiments, the number of planar faces (e.g., triangular planar facets) is equal to or greater than the sum of the number of sides of the input aperture (e.g., 8) and the number of sides of the output aperture (e.g., 4). Similarly, in various embodiments, the number of folds between the facets is equal to or greater than the sum of the number of sides of the input aperture (e.g., 8) and the number of sides of the output aperture (e.g., 4).

The output aperture 220 in this embodiment is a rectangle (e.g., a square) in order to efficiently transmit light to a rectangular photovoltaic cell. The input aperture 210 may comprise a shape corresponding to a shape of an input light. For example, in FIGS. 2 and 3, the input aperture 210 is characterized by an equiangular octagon, which may closely approximate a shape characterizing light capable of being received by the secondary (e.g., a shape characterizing light output by a primary reflector or lens). As one skilled in the art will appreciate, both the input aperture and output aperture may possess the shape of a polygonal with more or less sides than that shown in FIGS. 2, 3A, and 3B. The polygonal shape of the input and output apertures may vary from a true polygon (e.g., a closed shape consisting of a number of coplanar line segments, each connected end to end) due to the finite thickness of the material from which the secondary is folded.

If the polygons associated with the input and output apertures are regular polygons, in various embodiments the secondary will generally possess 4-fold or “quad” symmetry (i.e. invariant to 90 degree rotation) about the longitudinal or optical axis 225 (indicated by an “x”) that is associated with the tapered polyhedron. This longitudinal or optical axis 225 extends longitudinally through the center of secondary. However, in some embodiments, the polygons characterizing the input and output apertures may vary from the regular polygon shown.

The secondary may also be characterized by the number and orientation of vectors normal to its facets. In the case of the secondary 200, each of the facets 230 with sides (e.g., bases) abutting the output aperture 220 has a normal vector 213 from the centroid of the facet that intersects the secondary's longitudinal or optical axis. The secondary also includes a plurality of additional facets 232 with sides (e.g., bases) that abut the input aperture 210, each of these facets is characterized by a normal vector 215 from the centroid of the facet that does not intersect the secondary's longitudinal or optical axis. Such a configuration may increase mixing and thus provide increased uniformity in the distribution of light at the output aperture. (Note: the longitudinal or optical axis and normal vectors of facets are schematically represented, e.g., in FIGS. 3A and 3B, and thus, the actual location of the longitudinal or optical axis and normals may be different and depend on the geometry.) As described above, in some instances, a triangular facet 230 comprises a vertex and a base. For example, the vertex and base of facet 230 border the input aperture 210 and at the output aperture 220, respectively, while the vertex and base of facet 232 border the output aperture 220 and input aperture 210, respectively. In some instances, a point along the base (e.g., in the center) of a facet has a normal vector that intersects with the secondary's longitudinal axis.

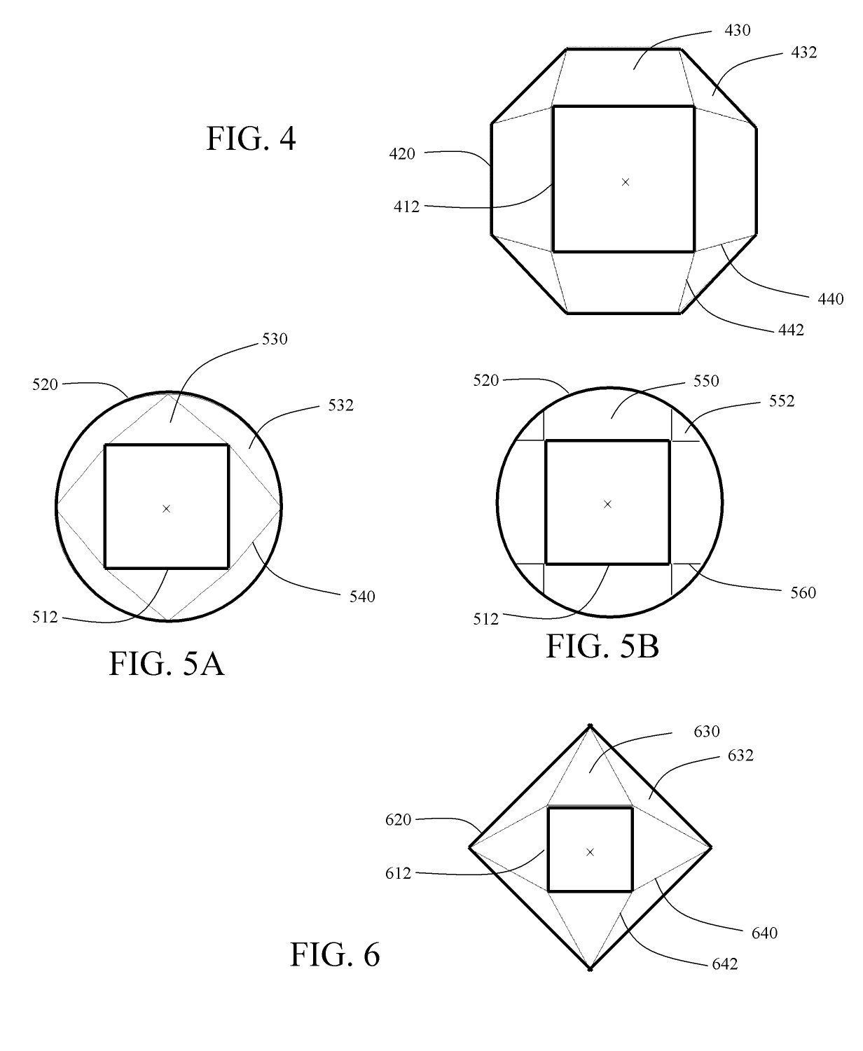

Illustrated in FIG. 4 is another embodiment of a secondary looking along its longitudinal axis. The input aperture 420 is characterized by an octagon and the output aperture 412 is characterized by a rectangle configured to, for example, couple with a square photovoltaic cell. The shape of the secondary approximates a tapered polyhedron farmed from a plurality of flat facets. The set of facets include parallelogram facets 430 that couple one side of the input aperture 420 to a parallel side of the output aperture 412. There are also triangular facets 432 that connect one side of the input aperture 420 to a corner or vertex on the output aperture 412. The facets are bounded by edges 440, 442 that span the length of the secondary. In some embodiments, depending, for example, on dimensions and/or orientations of the input and output apertures 420 and 410, the parallelogram facets 430 comprise rectangular facets or the parallelogram facets 430 comprise trapezoidal facets. For example, rectangular facets may be used to connect a side of the input aperture 420 to a side of the output aperture when the sides are of equal length and are within the same plane as each other. A trapezoidal facet may be used to connect a side of the input aperture 420 to a side of the output aperture when the sides are of different length and are within the same plane as each other. A triangular facet may be used to connect a side of the input aperture 420 to a side of the output aperture when the sides are not within the same plane as each other (for example, because the input aperture is rotated with respect to the output aperture).

In the example shown in FIG. 4, the reflector 200 has 8 planar facets: four triangular facets 432 and four trapezoidal facets. Accordingly, in various embodiments, the number of planar faces (e.g., triangular and trapezoidal planar facets) is equal to or greater than the sum of the number of sides of the input aperture (e.g., 8). The number of trapezoidal facets 420 is equal to or greater than the number of sides of the output aperture (e.g., 4). Similarly, the number of folds between the facets is equal to or greater than the sum of the number of sides of the input aperture (e.g., 8). In various embodiments, the number of triangular planar facets 432 is equal to or greater than the number of sides of the input aperture (e.g. 8) minus the number of side of the output aperture (e.g., 4). In the embodiment shown, the input aperture 420 is larger (e.g., has a larger area) than the output aperture 412. In certain embodiments, the photovoltaic may be disposed closer to (e.g., at or proximal to) the output aperture 412 than to the input aperture 420.

Illustrated in FIG. 5A is another embodiment of a secondary looking along its longitudinal axis. The input aperture 520 is characterized by a circle or ellipse and the output aperture 512 is characterized by a rectangle configured to, for example, couple with a square photovoltaic cell. The shape of the secondary approximates a tapered polyhedron formed from a plurality of flat faces and conical (e.g. curved) faces separated by side edges 540. The set of faces include triangular faces 530 having bases that couple the input aperture 520 to a corresponding side of the output aperture 522. There are also conical faces 532 that connect a section of the input aperture 520 to a corner/vertex on the output aperture 512. In the example shown in FIG. 5A where the output aperture has four sides, four triangle faces 530 having respective four bases are used. Similarly, four conical faces 532 having four bases on the input aperture side are used. Accordingly, although the input aperture 520 may be divided into four quarter sections by the conical faces 532, as there are, in this case, four vertices to connect to on the output aperture 512, a section may comprise other fractions of the input aperture. In various embodiments such as shown, the faces are bounded by edges 540, which span the length of the secondary. The conical face 532 may comprise straight edges connecting a vertex to a curved portion and connecting the conical face 532 to triangular faces 530. In the embodiment shown, the input aperture 520 is larger (e.g., has a larger area) than the output aperture 512. In certain embodiments, the photovoltaic may be disposed closer to (e.g., at or proximal to) the output aperture 512.

FIG. 5B shows another embodiment in which two types of conical faces connect a round input aperture 520 and a square output aperture 512. The first group of faces 550 connects a section of the input aperture 520 to a side of the output aperture 512. A second group of faces 552 connects a section of the input aperture 520 to a corner/vertex on the output aperture 512. In the example shown in FIG. 5B where the output aperture has four sides, the first group includes four faces 550. Similarly, in the example shown where the output aperture has four corners, the second group also includes four faces 552. The faces are bounded by edges 560, which span the length of the secondary. In the embodiment shown, the input aperture 520 is larger (e.g., has a larger area) than the output aperture 512. In certain embodiments, the photovoltaic may be disposed closer to (e.g., at or proximal to) the output aperture 512.

Illustrated in FIG. 6 is another embodiment of a secondary looking along its longitudinal axis. The input aperture 620 is characterized by a rectangle and the output aperture 612 is characterized by another rectangle rotated (e.g., by 45 degrees) with respect to the input aperture 620. The shape of the secondary approximates a tapered polyhedron formed from a plurality of flat facets separated by side edges. The set of facets include triangular facets 630 that couple a corner/vertex on input aperture 620 to a corresponding side of the output aperture 622. The bases of the triangular facets 630 are located at the sides of the output aperture 612. The vertices of the triangular facets 630 are located at the corners of the input aperture 620. There are also triangular facets 632 that couple a side edge on input aperture 620 to a corresponding corner/vertex on the output aperture 612. The bases of the triangular facets 632 are located at the sides of the input aperture 620. The vertices of the triangular facets 632 are located at the corners of the output aperture 612. Likewise the number (e.g., 8) of triangular facets 630, 632 is equal to or greater than the number of sides/corners (e.g., 4) on the input aperture 620 plus the number of sides/corners (e.g., 4) on the output aperture 612. The facets are bounded by edges 640, 642 that span the length of the secondary. The number (e.g., 8) of edges 640, 642, between facets is equal to the number of triangle facets 630 (e.g., 4) plus the number of triangle facets 632 (e.g., 4) or the number of sides/corners on the input aperture 620 plus the number of sides/corners on the output aperture 612.

In the embodiment shown in FIG. 6, the input aperture 620 is larger (e.g., has a larger area) than the output aperture 612. In certain embodiments, the photovoltaic may be disposed closer to (e.g., at or proximal to) the output aperture 612 than to the input aperture 620.

As describe above, the number of facets extending from an input aperture to an output aperture and the number of facets extending from an output aperture to an input aperture may be determined, for example, at least partly based on the number of sides and the orientations of the input and output apertures. For reflectors comprising polygonal input and output apertures, the number of rectangular or trapezoidal facets may be equal to the total number of sides of the input aperture which are within the same plane as a side of the output aperture. The number of triangular facets may be equal to the total number of sides on either the input or output aperture that are not within the same plane as a side on the opposite aperture.

Various embodiments describe herein include four or more reflective surfaces with normal vectors from the centroid of the surface which do not intersect the optical axis and so when projected on the cell plane contain components along both cell dimensions. This serves to increase the throughput per unit reflector length compared to designs that do not include facets with normal vectors from the centroid of the surface which do not intersect the optical axis such that when projected on the cell plane contain components along both cell dimensions. As one skilled in the art will appreciate, apertures with higher degree (>8) polygons can also be constructed with this same symmetry.

For various embodiments, some general rules govern the relationship between (1) the aperture size and cell size, and (2) the aperture size and reflector length of the reflector and the cell size. The etendue is the product of the secondary aperture area and the projected solid angle “PSA”. For a square lens of side s and focal length f, the semi-angle subtended by the lens at the focus is γ=arctan(s/f), and the PSA is given by PSA=arctan(sin γ)*sin γ. As an example, for a square lens of aperture 325 mm and focal length 303 mm, the projected solid angle is 0.83 sr. For a square solar cell of 10 mm immersed in air, the largest aperture consistent with complete light transfer is then 376 mm², by etendue invariance, corresponding to hemispherical intensity on the cell. For a circular aperture, this corresponds to a diameter of 21.9 mm, and this diameter will circumscribe polygonal aperture geometries. At such oblique angles of incidence reflectivity loss is high even for a cell or cover glass with antireflection coating. In some embodiments, the angles are restricted, resulting in apertures of somewhat smaller area.

In some embodiments, the length of the reflector may be controlled by limiting the effective average number of reflections <n>, where <n>=log η/log ρ, ρ is the reflectivity and η is the energy transfer efficiency of the secondary. If <n> is too low then the uniformity of the illumination suffers, and if <n> is too great then throughput suffers because of the absorption loss in the mirror coating. For example in the case of the embodiment shown in FIG. 2 with an aperture inscribed in a 18 mm diameter and a length of 23 mm long, <n>˜1 for ρ=0.95. For a suitable reflector, <n> is generally in the range 0.5 to 3.

Materials with which to form a secondary include protected silver or aluminum thin film coatings on anodized aluminum substrates such as the coil produced by the Alanod Company of Ennepetal, Germany.

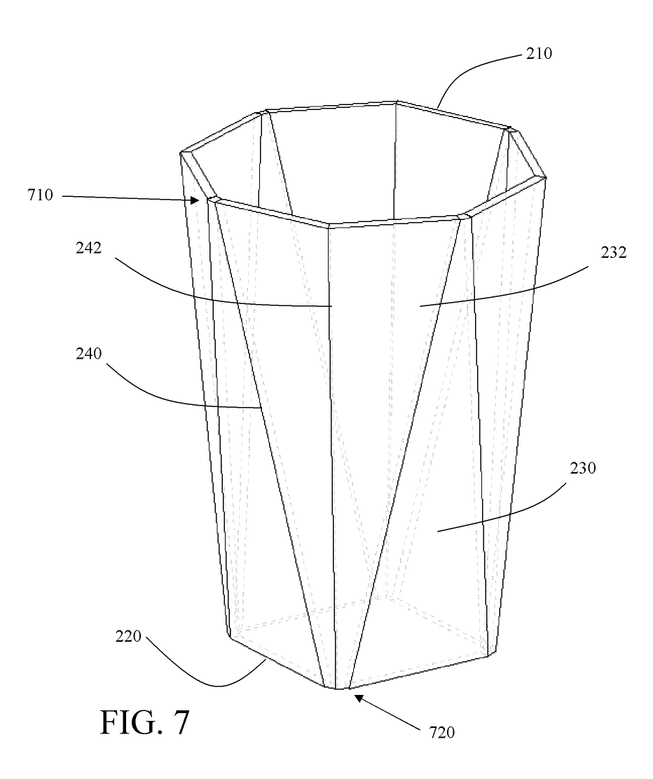

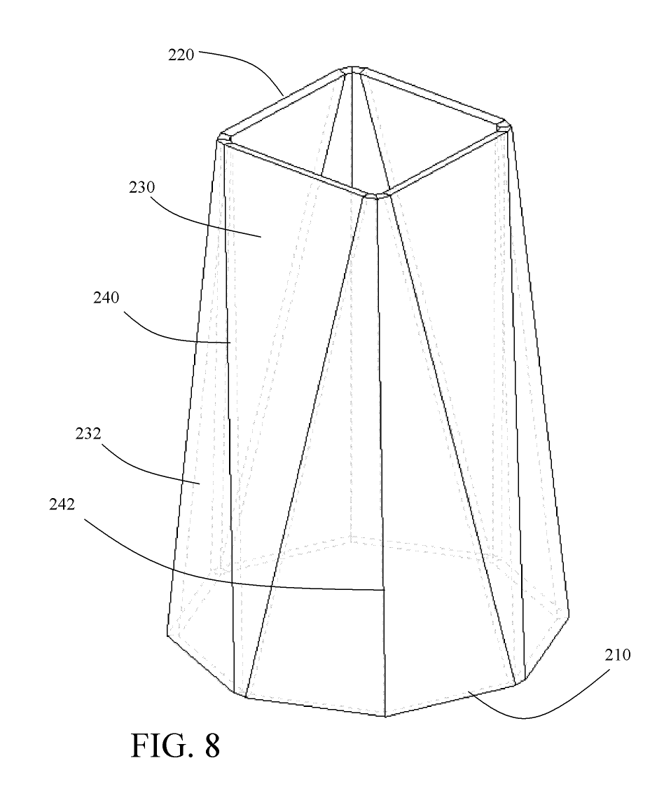

Illustrated in FIGS. 7 and 8 are side views of the secondary reflector with octagonal input aperture shown above in FIGS. 2, 3A, and 3B. The facets 230, 232 that connect the input aperture 210 to the output aperture 220 are substantially flat. These facets need not necessarily be truly planar faces. As can be seen in this illustration, the facets in some embodiments include minor bends in proximity to a fold edge 240, 242. In particular, a radius joins two facets at a fold edge. The radius, which is a byproduct of the manufacturing, is generally more pronounced on the outer surface of the secondary than the inner surface of the secondary due to the finite thickness of the sheet metal from which the secondary is folded. In various embodiments, at least 90%, 95%, 97%, 98%, 99%, 99.5%, 99.9%, 99.95%, or 99.99% of the face is flat or have an average radius that is at least about 20, 50, 100, 500 or 1000 times greater than a radius of the reflector. Similarly, although the facets 230, 232 are generally triangular in shape, the facets are not perfect triangles. For example, the triangular facets 230, 232 do not come to perfect points at vertices 710 and 720.

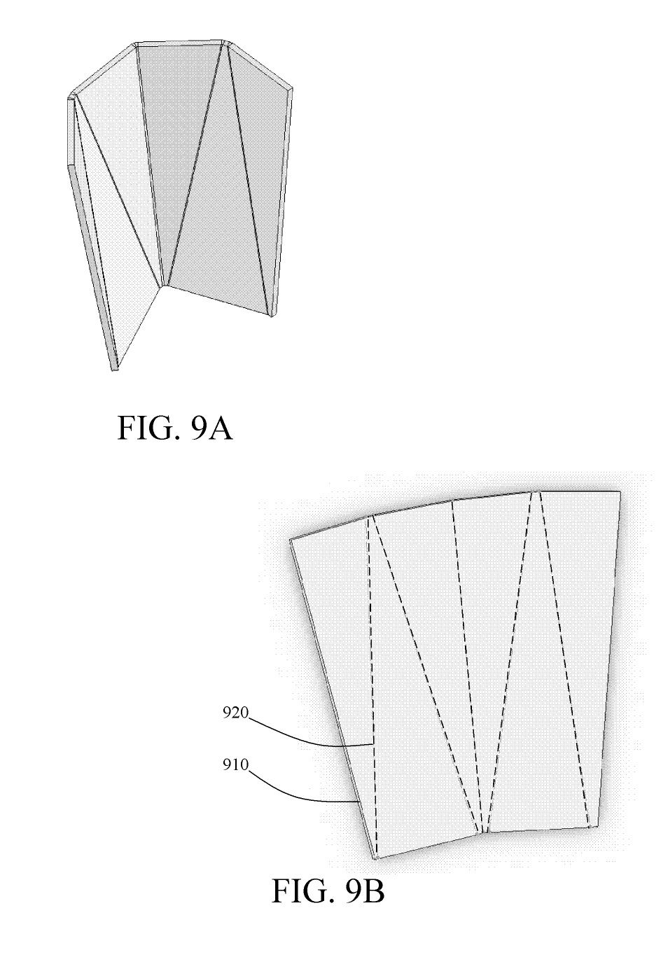

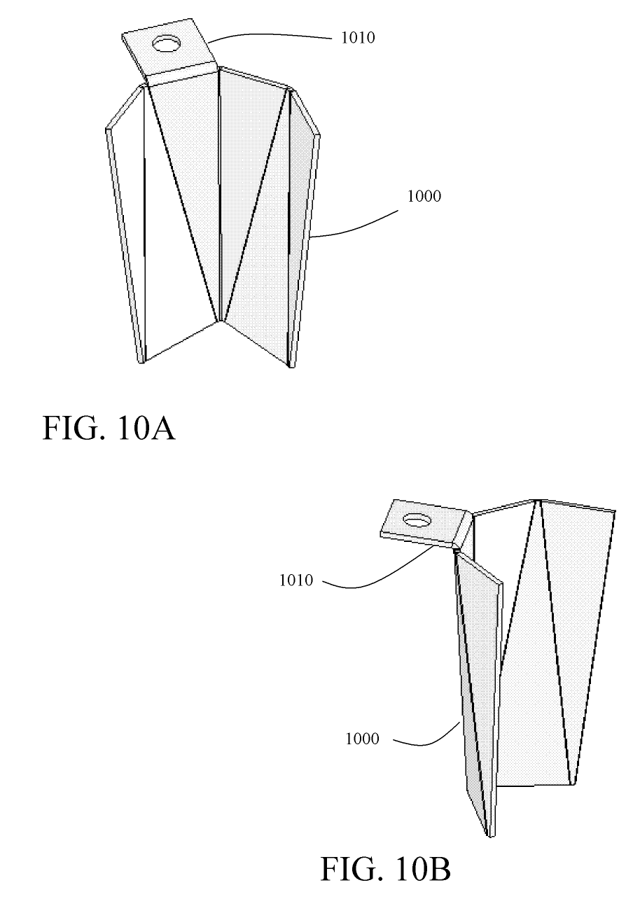

Illustrated in FIG. 9A is a portion of the secondary reflector shown in FIGS. 7 and 8. The portion of the secondary corresponds to a section of the tapered polyhedron that spans the full distance between the input and output apertures and subtends approximately 180 degrees of the circumference of the complete secondary. As shown, the upper section corresponds to 4 sides of the octagonal input aperture while the lower section corresponds to the 2 sides of the square output aperture. Two of these half sections may be coupled together during receiver assembly to form a complete and functional secondary mirror. In some embodiments, the section comprises a different fraction of the tapered polyhedron. For example, two sections may comprise 25% and 75% of the tapered polyhedron, or four sections may comprise 25% of the tapered polyhedron.

Illustrated in FIG. 9B is a section of sheet material 910, which when folded at the dashed lines 920, yields the half-section of secondary shown in FIG. 9A. As described above, some of the facets are substantially isosceles triangles and some of the facets are right triangles. For example two of the triangular facets in the section shown in FIGS. 9A and 9B are isosceles triangles and four of the triangular facets are right triangles. In the embodiment shown, the top and bottom borders of the material comprise a plurality of straight lines. In other embodiments, for example those in which one of the input and output apertures are characterized with an elliptical or circular shape, one or both of the borders may comprise curved lines.

This section of the tapered polyhedron that joins the input aperture 210 and output aperture 220 is “developable,” i.e., having a zero Gaussian curvature. Accordingly, this section may be made by cutting and folding (or bending) sheet metal. Here two similar sections as shown in FIG. 9A each being developable having zero Gaussian curvature may be cut and folded and assembled together to form the complete tapered polyhedron reflector. A single first sheet form a first half having zero Gaussian curvature and a single second sheet second half having zero Gaussian curvature which can be combined to form the tapered hollow reflective polyhedron.

In other embodiments more or less sheets may be used. For example 4 or 3 sheets may be cut and folded and combined together to form the complete tapered hollow reflective polyhedron. The sheets after being folded may thus form a thirds or quarters of the tapered polyhedron reflector. The thirds or quarters may have zero Gaussian curvature. In some embodiments, a single sheet may be folded to form the complete tapered hollow reflective polyhedron. This folded sheet may have zero Gaussian curvature.

Illustrated in FIGS. 10A and 10B is another embodiment of the half section 1000 of the exemplary secondary shown in FIGS. 7 and 8. This embodiment is consistent with that shown in FIG. 9A except for the inclusion of a mounting tab 1010. The mounting tab 1010 is configured to fixedly attach to a mounting structure that rigidly affixes the section 1000 of secondary to another structure, such as an output structure (e.g., a photovoltaic cell) to which the light from the secondary is directed or an input structure (e.g., a primary reflector or lens) from which light is received. In some instances, the output structure comprises the mounting structure. A secondary reflector and/or section 1000 may include one or more of the mounting tabs 1010. The mounting tab 1010 may be configured such that substantially no movement of the section 1000 is possible with the tab 1010 securely engaged or such that movement is limited following engaging of the tab.

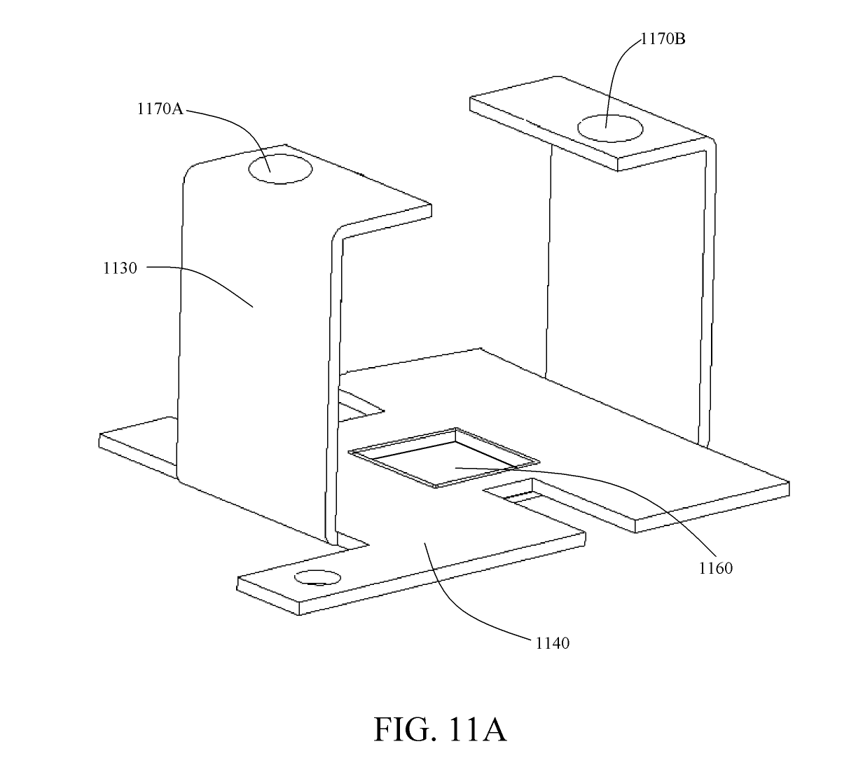

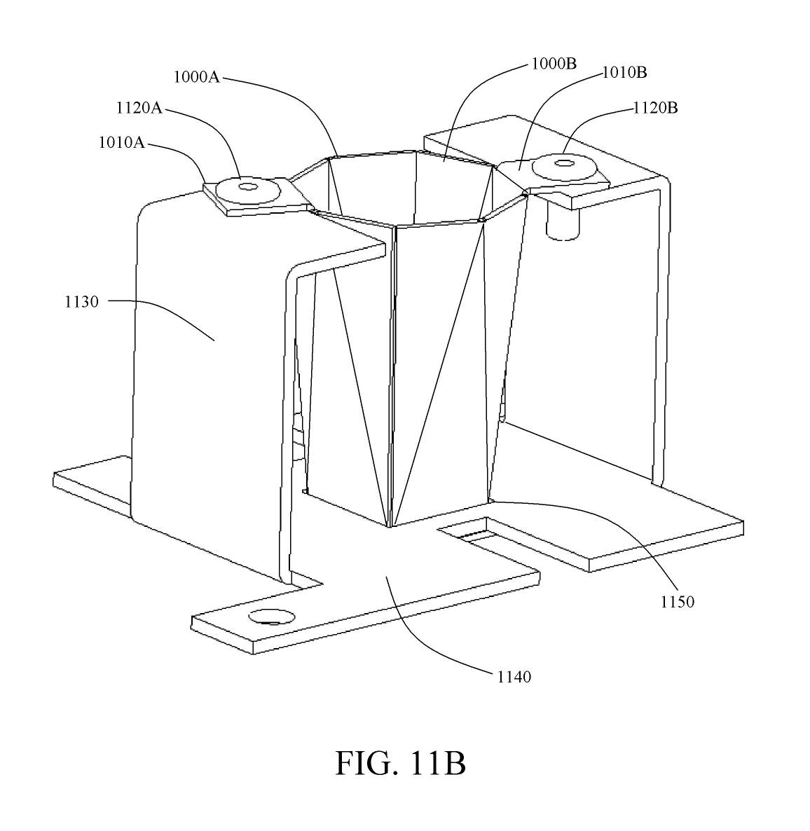

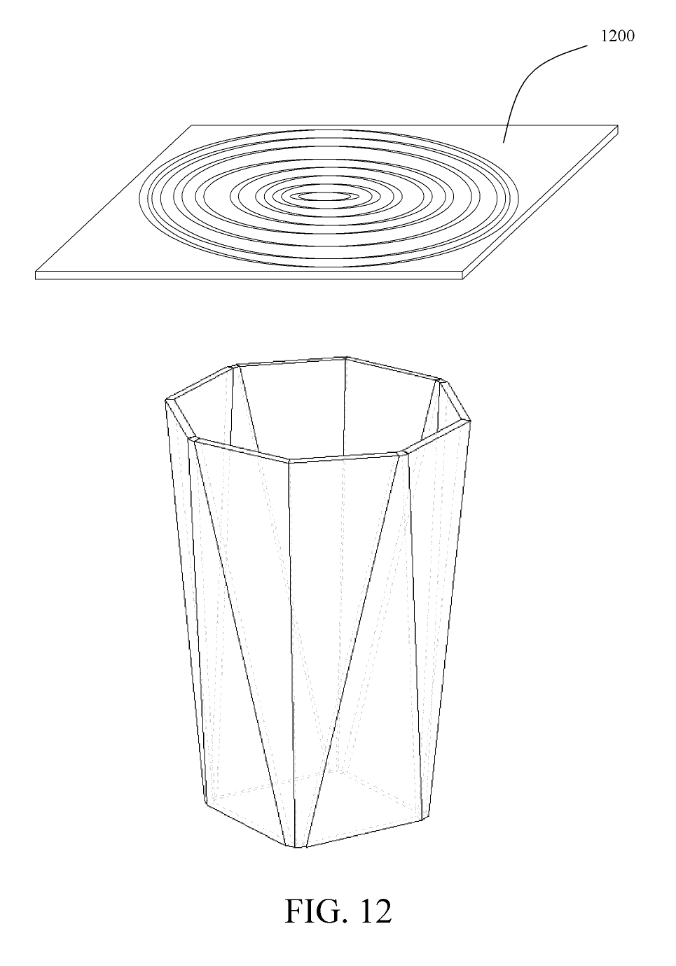

FIG. 11A shows a support structure for mounting a secondary reflector, and FIG. 11B shows a complete secondary assembly including the support structure and the reflective secondary for installation in a receiver. The secondary assembly includes a left secondary half section 1000A and right secondary half section 1000B that are mounted in opposing fashion to form a tapered polyhedron. The half sections 1000A, 1000B are mechanically secured together with a mounting assembly which includes, in this instance, two risers 1130 and a base 1140 such that the output aperture of the resulting reflector mounts to the hole 1150 in the base 1140. This mounting arrangement positions the reflector aperture proximal to the face of a photovoltaic cell 1060. The mounting tabs 1010A and 1010B may be positioned over holes 1170A and 1170B in the risers and secured with fasteners (e.g., screws, bolts, rivets, etc) 1120A and 1120B. In other embodiments (e.g., embodiments in which more than two sections are used), other mounting assemblies may be used. In some embodiments, the mounting tabs 1010A and 1010B are not used, and the risers 1130 apply a force to the sections 1000A and 1000B to limit or prevent movement. The lower sides of the secondary half sections are inserted into and secured by an aperture 1150 in the center of the mounting base 1140. In other embodiments, the lower sides of the sections are supported by other components, and thus may not be secured by the aperture 1150. For example, the risers 1130 may be configured to be adjacent to (and possibly provide force to or attach to) sides near the input and output apertures of the reflector. Other configurations are possible.

FIG. 12 schematically illustrate a primary 1200 disposed with respect to the secondary reflector to direct light (e.g., sunlight) into the input aperture of the secondary reflector. The primary 1200 shown comprises a lens such as a Fresnel lens. The primary 1200 is disposed forward or above the primary 1200. Other types of primary optical elements (e.g., mirrors or reflective optical elements) may be employed and the arrangement with respect to the secondary (e.g., distance between) may be varied in other embodiments.

While the invention has been discussed in terms of certain embodiments, it should be appreciated that the invention is not so limited. The embodiments are explained herein by way of example, and there are numerous modifications, variations and other embodiments that may be employed that would still be within the scope of the present invention.

Accordingly, a wide variety of alternative configurations are possible. For example, components (e.g., mirrors, reflective surfaces, supports, etc.) may be added, removed, or rearranged. Similarly, processing and method steps may be added, removed, or reordered.

For purposes of this disclosure, certain aspects, advantages, and novel features of the invention are described herein. It is to be understood that not necessarily all such advantages may be achieved in accordance with any particular embodiment of the invention. Thus, for example, those skilled in the art will recognize that the invention may be embodied or carried out in a manner that achieves one advantage or group of advantages as taught herein without necessarily achieving other advantages as may be taught or suggested herein.

What is claimed is:

1. A reflector comprising:
a tapered polyhedron comprising a plurality of substantially planar facets and having an optical axis extending therethrough, wherein the inner surface of the tapered polyhedron is reflective;
a rectangular output end at an end of the tapered polyhedron; and
a polygon input end at an end of the tapered polyhedron opposite the rectangular output end,
wherein some of the substantially planar facets have surface normals that intersect the optical axis and some of the substantially planar facets have surface normals skew to the optical axis and wherein the polygon comprises five or more sides.

2. The reflector of claim 1, wherein the output aperture is characterized by a square.

3. The reflector of claim 1, wherein the tapered polyhedron exhibits quad symmetry about a longitudinal axis.

4. The reflector of claim 1, wherein the tapered polyhedron is a developable surface.

5. The reflector of claim 1, wherein said polygon input end and said rectangular output end comprise apertures.

6. The reflector of claim 1, wherein said substantially planar facets comprise a plurality of triangular facets.

7. The reflector of claim 1, wherein said substantially planar facets comprise a plurality of rectangular facets.

8. The reflector of claim 1, wherein said substantially planar facets comprise a plurality of trapezoidal facets.

9. The reflector of claim 1, wherein the reflector comprises at least one of silver or aluminum.

10. The reflector of claim 1, wherein the reflector comprises at least one of protected silver, an aluminum thin film coating, and an anodized aluminum substrate.

11. An optical system comprising:
a reflector comprising:
a tapered polyhedron comprising a plurality of substantially planar facets and having an optical axis extending therethrough, wherein the inner surface of the tapered polyhedron is reflective;
a rectangular output end at an end of the tapered polyhedron; and
a polygon input end at an end of the tapered polyhedron opposite the rectangular output end,
wherein some of the substantially planar facets have surface normals that intersect the optical axis and some of the substantially planar facets have surface normals that do not intersect the optical axis and wherein the polygon comprises five or more sides; and
a solar cell, the reflector disposed to direct light along an optical path to the solar cell.

12. The optical system of claim 11, further comprising a focusing element.

13. The optical system of claim 12, wherein the focusing element comprises at least one of a lens and a mirror.

14. A method of manufacturing a solar energy conversion assembly, the method comprising:
providing a reflector comprising:
a tapered polyhedron comprising a plurality of substantially planar facets and having an optical axis extending therethrough, wherein the inner surface of the tapered polyhedron is reflective;
a rectangular output end at an end of the tapered polyhedron; and
a polygon input end at an end of the tapered polyhedron opposite the rectangular output end,
wherein some of the substantially planar facets have surface normals that intersect the optical axis and some of the substantially planar facets have surface normals skew to the optical axis and wherein the polygon comprises five or more sides;
disposing the reflector such that light output from the output end of the reflector is directed towards a solar cell.

15. A reflector comprising:
a tapered polyhedron comprising a plurality of substantially planar facets and having an optical axis extending therethrough, wherein the inner surface of the tapered polyhedron is reflective;
a polygon input end at an end of the tapered polyhedron; and
a polygon output end at an end of the tapered polyhedron opposite the input end,
wherein some of the substantially planar facets have surface normals that intersect the optical axis and some of the substantially planar facets have surface normals skew to the optical axis and wherein a number of sides associated with the polygon of the input end is different than a number of sides associated with the polygon of the output end.

16. The reflector of claim 15, wherein the tapered polyhedron is a developable surface.

17. The reflector of claim 15, wherein the output end is characterized by a square.

18. The reflector of claim 17, wherein the tapered polyhedron exhibits quad symmetry about a longitudinal axis.

19. The reflector of claim 15, wherein said polygon input end and said polygon output end comprise apertures.

20. The reflector of claim 15, wherein said substantially planar facets comprise a plurality of triangular facets.

21. The reflector of claim 15, wherein said substantially planar facets comprise a plurality of rectangular facets.

22. The reflector of claim 15, wherein said substantially planar facets comprise a plurality of trapezoidal facets.

23. The reflector of claim 15, wherein the reflector comprises at least one of silver or aluminum.

24. The reflector of claim 15, wherein the reflector comprises at least one of protected silver, an aluminum thin film coating, and an anodized aluminum substrate.

25. The reflector of claim 15, wherein the polygon of the input end comprises at least one side that does not share a plane with any of the sides of the polygon of the output end.

26. An optical system comprising:
a reflector comprising:
a tapered polyhedron comprising a plurality of substantially planar facets and having an optical axis extending therethrough, wherein the inner surface of the tapered polyhedron is reflective;
a polygon input end at an end of the tapered polyhedron; and
a polygon output end at an end of the tapered polyhedron opposite the input end,
wherein some of the substantially planar facets have surface normals that intersect the optical axis and some of the substantially planar facets have surface normals that do not intersect the optical axis and wherein a number of sides associated with the polygon of the input end is different than a number of sides associated with the polygon of the output end; and
a solar cell, the reflector being configured to direct light towards the solar cell.

27. The optical system of claim 26, further comprising a focusing element.

28. The optical system of claim 26, wherein the focusing element comprises at least one of a lens and a mirror.

29. A method of manufacturing an assembly for solar energy conversion, the method comprising:
providing a reflector comprising:
a tapered polyhedron comprising a plurality of substantially planar facets and having an optical axis extending therethrough, wherein the inner surface of the tapered polyhedron is reflective;
a polygon input end at an end of the tapered polyhedron; and
a polygon output end at an end of the tapered polyhedron opposite the input end,
wherein some of the substantially planar facets have surface normals that intersect the optical axis and some of the substantially planar facets have surface normals skew to the optical axis and wherein a number of sides associated with the polygon of the input end is different than a number of sides associated with the polygon of the output end; and
disposing the reflector to direct light along an optical path to the solar cell.
